(19) United States
(12) Patent Application Publication
(10) Pub. No.: US 2021/0135622 A1
(43) Pub. Date: May 6, 2021

(54) COMBINED HEAT AND ELECTRICITY SOLAR COLLECTOR WITH WIDE ANGLE CONCENTRATOR

(71) Applicant: The Regents of the University of California, Oakland, CA (US)

(72) Inventors: Roland WINSTON, Merced, CA (US); Lun JIANG, Merced, CA (US)

(73) Assignee: The Regents of the University of California, Oakland, CA (US)

(21) Appl. No.: 16/605,099

(22) PCT Filed: Apr. 16, 2018
(86) PCT No.: PCT/US2018/027830

§ 371 Date: Oct. 14, 2019

Related U.S. Application Data
(60) Provisional application No. 62/485,798, filed on Apr. 14, 2017.

(51) Int. Cl. H02S 40/44; F24S 10/70

(52) U.S. Cl. CPC H02S 40/44; F24S 10/70

(57) ABSTRACT

Non-imaging solar collectors that generate both electrical energy and thermal energy through the use of a novel solar absorber assembly inside a transparent housing with a wide-angle concentrator are disclosed. One or more minichannels or heat pipes comprise part of the absorber assembly, and effectively remove heat from photovoltaic solar cells adjacent and/or attached to the minichannels or heat pipes, thereby cooling and improving the efficiency of the solar cells while at the same time transferring heat to a fluid flowing through the minichannel(s). Also disclosed are methods of manufacturing non-imaging solar collectors that generate both electrical and thermal energy.

### CROSS-REFERENCE TO RELATED APPLICATIONS

Pursuant to 35 U.S.C. § 371, this application is a U.S. National Phase application of PCT/US2018/027830 filed Apr. 16, 2018, which claims priority pursuant to 35 U.S.C. § 119(e) to U.S. Provisional Patent Application No. 62/485,798, filed Apr. 14, 2017, which applications are specifically incorporated herein, in their entireties, by reference as if fully set forth herein.

### FIELD OF THE INVENTION

The present invention generally relates to the field of solar energy. Specifically, embodiments of the present invention relate to a combined heat and power solar collector that concentrates solar energy using a wide angle concentrator and nonimaging optics to produce both electricity and hot water.

### DISCUSSION OF THE BACKGROUND

Conventional solar electric systems generate electric power directly from sunlight using photovoltaic (PV) cells. PV devices generally employ light concentrators to concentrate sunlight onto photovoltaic surfaces, thereby maximizing the amount of energy collected for the purpose of electrical power production. Use of nonimaging optics for solar concentration provide the widest possible acceptance angles and, therefore, are more efficient in collecting energy from the sun when compared with conventional imaging optics (such as parabolic reflectors), or systems that track the position of the sun.

Conventional solar thermal collectors for space heating, domestic hot water and other applications collect heat by absorbing solar radiation using solar hot water panels, solar parabolic troughs or solar air heaters. Flat plate collectors are the most common type of solar thermal collector, and typically utilize a dark-flat plate absorber and a heat-transfer fluid, such as water or air. Efficiently transferring heat from the sun to a fluid medium continues to challenge engineers and designers of solar thermal collectors.

Most typically, the conventional solar systems described above are separate systems—they will generate either heat or electricity, but not both. In recent years, combined heat and power (CHP) collector systems have been developed, but generally, these CHP systems use solar cells on a flat heat sink without any optics. This increases the cost of the material by utilizing only one side of the absorber. Through the use of a nonimaging concentrator, both sides of the absorber may advantageously be exploited, further improving the efficiency and reducing the costs of the CHP solar system.

Therefore, there is a strong need to provide a CHP solar collector utilizing a nonimaging concentrator to improve performance and reduce the costs of conventional solar electricity and solar thermal collector systems.

### SUMMARY OF THE INVENTION

The present invention advantageously provides for both the efficient production of electricity through the use of PV solar cells as well as the efficient collection of thermal energy through heat transfer to a fluid medium, all within the same solar collector. In preferred embodiments, non-imaging solar collectors generate both electrical energy and thermal energy through the use of a novel absorber assembly, using a wide-angle concentrator. One or more minichannels that comprise part of the absorber assembly, effectively remove heat from the solar cells, thereby improving the efficiency of the solar cells while at the same time transferring thermal energy to a fluid (most typically water), flowing through the minichannel(s).

It is therefore an object of the invention to provide an improved CHP solar collector utilizing nonimaging optics and a wide angle concentrator.

It is a further object of the invention to provide an improved nonimaging solar collector wherein PV solar cells operate at improved efficiencies as a result of the removal of heat from within the solar cells.

It is a further object of the invention to provide an improved nonimaging solar collector wherein heat is transferred to a fluid flowing through minichannels within the nonimaging solar collector housing to provide hot water for consumer use.

It is another object of the invention to provide an improved CHP solar collector having an absorber assembly comprising one or more minichannels and at least one solar cell.

It is another object of the invention to provide an improved CHP solar collector utilizing nonimaging optics having a transparent housing, a wide angle concentrator, and an absorber assembly within the housing, wherein the absorber assembly both converts solar light into electricity and transfers heat to a fluid flowing through the assembly.

It is another object of the invention to provide a method of manufacturing an improved CHP solar collector for providing both electricity and thermal energy.

It is to be understood that both the foregoing general description and the following detailed description are exemplary, but not restrictive, of the invention. A more complete understanding of the improved solar collector and the methods disclosed herein will be afforded to those skilled in the art.

### BRIEF DESCRIPTION OF THE DRAWINGS

FIG. 1A is a top view of a non-imaging solar collector for the generation of both heat and electricity according to an embodiment of the present invention.

FIG. 1B is an elevation view of the non-imaging solar collector of FIG. 1A.

FIG. 1C is a section view of the non-imaging solar collector of FIG. 1A, showing the absorber assembly at a 180 degree position in the tubular housing.

FIG. 2A is a section view of a non-imaging solar collector showing the absorber assembly at a 90 degree position in the tubular housing.

FIG. 2B is a section view of a non-imaging solar collector showing the absorber assembly at about a 225 degree position in the tubular housing.

FIG. 3A is an elevation view of an absorber assembly showing a bulkhead to redirect fluid flow in a top minichannel to the opposite direction of the flow in a bottom minichannel of the assembly.

FIG. 3B is a section view of the absorber assembly of FIG. 3A, showing the bottom and top minichannels in a stacked arrangement.

FIG. 4 shows non-imaging solar collector components including a housing with end cap and lock ring, and an absorber assembly with solar cells, minichannel and double-sided tape.

FIG. 5 is an enlarged perspective view of a threaded end of a housing, end cap and lock ring.

FIG. 6 is a side elevation of a housing with a domed end, straight section, taper section and threaded section, according to an embodiment of the present invention.

FIG. 7A is a rear view of solar cells interconnected using thin conductors.

FIG. 7B is a perspective view showing the attachment of solar cells to a minichannel using a double-sided heat tape.

FIGS. 8A and 8B show two cutting patterns for a IBC solar cell.

FIG. 8C shows a portion of an IBC solar cell contact structure.

FIG. 9 is a schematic of a gravitational heat pipe.

FIG. 10 is a sectional view of a minichannel according to an embodiment of the present invention.

FIG. 11 is a perspective view of a manifold design for a minichannel heat pipe according to an embodiment of the present invention.

FIG. 12 is a graph of temperature change along the length of a heated portion of a minichannel for working fluid flow rates.

FIG. 13 is a schematic showing minichannel temperature distribution.

FIG. 14 shows temperature distribution in a direct flow configuration.

FIG. 15 is a perspective view of a portion of a non-imaging solar collector showing transversal and longitudinal angles.

FIG. 16 is a screenshot of a transversal angle analysis of a non-imaging solar collector.

FIG. 17 is a graph of the radiation on the left side of an absorber.

FIG. 18 is a graph of radiation on the right side of an absorber.

FIG. 19 shows radiation for an arrangement of solar cells along the axis of an absorber.

FIG. 20A is a screenshot of a ray tracing with the absorber in the 180° position.

FIG. 20B is a graph of the absorbed power of the absorber in the position of FIG. 20A.

FIG. 21A is a screenshot of a ray tracing with the absorber in the 90° position.

FIG. 21B is a graph of the absorbed power of the absorber in the position of FIG. 21A.

FIG. 22A is screen shot of a ray tracing with the absorber in the 135° position.

FIG. 22B is a graph of the absorbed power of the absorber in the position of FIG. 22A.

FIG. 23A is a graph of air stream circulation with the absorber in the 90° position.

FIG. 23B is a graph of air stream circulation with the absorber in the 180° position.

FIG. 24A is a graph of convection heat loss with the absorber in the 180° position.

FIG. 24B is a graph of convection heat loss with the absorber in the 135° position.

FIG. 24C is a graph of convection heat loss with the absorber in the 90° position.

FIG. 25 is a graph of free convection heat loss as a function of working temperature.

FIG. 26 is a graph of spectral properties of typical commercially available solar cells.

FIG. 27 is a graph of optical properties of a TCO layer as a function of wavelength.

FIG. 28 is a graph of the emissivity of glass at different angles as a function of wavelength.

### DETAILED DESCRIPTION OF THE PREFERRED EMBODIMENTS

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications, and equivalents that may be included within the spirit and scope of the invention. Furthermore, in the following detailed description of the present invention, numerous specific details are set forth in order to provide a thorough understanding of the present invention. However, it will readily be apparent to one skilled in the art that the present invention may be practiced without these specific details.

Non-imaging PV solar collectors that generate electricity are well known in the art (see e.g., U.S. Pat. Nos. 5,289,356, 4,387,961, 4,359,265, 4,230,095, 4,003,638, 4,002,499 and 3,597,031). Likewise, solar collectors that collect solar thermal energy to produce heat are also well known in the art (see e.g., U.S. Pat. Nos. 9,383,120 and 7,971,587). In addition, a limited number of combined heat and power (CHP) solar systems have been developed (see e.g., Winston, WO2012030744, published Aug. 3, 2012). All of these referenced patents and publications are incorporated herein by reference.

Embodiments of the present invention provide for improved CHP solar systems and methods of manufacturing the same, utilizing nonimaging optics and wide-angle concentrators for solar concentration, minichannels (typically, aluminum minichannels) for thermal collection, and commercially-available solar cells for electricity production, all packaged in an inexpensive housing. By replacing the conventional packaging of solar panels and flat-plate thermal collectors with low-cost optics, a cost-competitive solar CHP collector is created that can be assembled into an array. Such CHP collectors efficiently produce both electricity and thermal energy, thereby providing significant improvement over conventional solar collectors that produce only electricity or only thermal energy and previously developed CHP collectors.

Combined Heat and Electricity Solar Collector with Wide Angle Concentrator

### Structure of Solar Collector

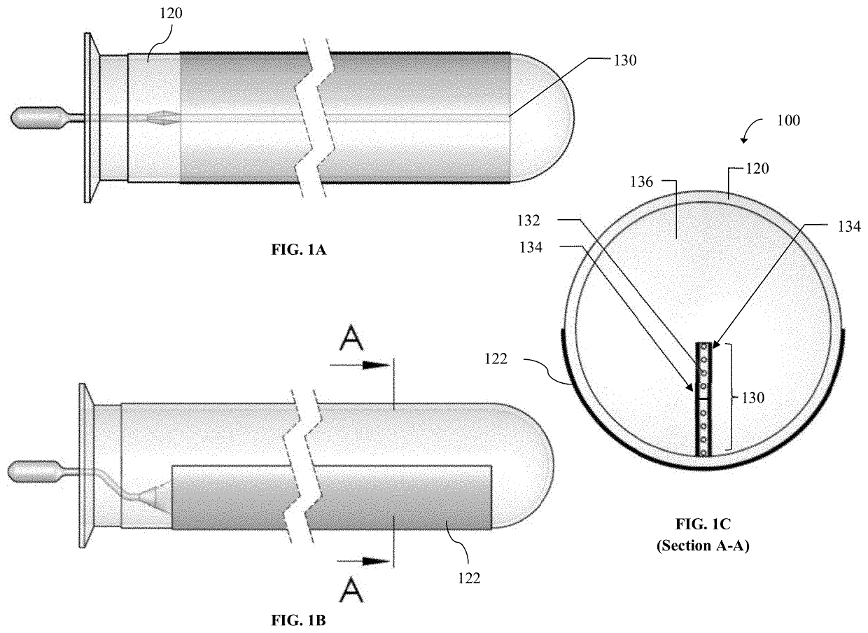

Referring now to FIGS. 1A-1C, the instant solar collector 100 typically comprises a transparent housing 120, which allows light rays to penetrate to the interior of the housing 120, a reflective coating 122 on a portion of the housing 120 to concentrate the light rays, and an absorber assembly 130, which absorbs both the concentrated light rays and the thermal energy to produce both power and heat. The absorber assembly 130 may comprise one or more minichannels 132 and at least one PV solar cell 134. The housing 120 may be glass, PLEXIGLAS, polycarbonate, acrylic and/or other plastic materials having a high degree of light transmission, clarity and strength at the operating temperatures of the solar cells discussed herein. Most typically, the housing will comprise borosilicate and/or soda lime glass. Borosilicate (also called PYREX) glass is a low iron glass with a high transparency (91.8% transmissivity) and low thermal expansion rate (3.3e-6 m/m ° C.). Because of these properties, borosilicate glass may be used in preferred embodiments.

The housing 120 as shown has a circular cross-section, but in other embodiments may comprise a conical, parabolic or other geometric-shaped cross-section. The typical housing 120 having a circular cross section may range from 40 mm to 125 mm in diameter, most typically 70 mm, and from 1.5 m to 2.7 m in length, although longer housings may be used so long as they may be easily lifted, transported and installed. The housing 120 with a circular cross-section is easily and cost-effectively produced.

The interior of the housing 120 may be evacuated (i.e., the interior may be a vacuum or partial vacuum), or, in other aspects, may comprise an inert gas 136 (e.g., argon, helium, radon, etc.). Most typically, the inert gas is argon at atmospheric pressure (1 atm.), although other pressures may also be utilized.

A portion of a surface of the housing 120 is coated with a reflective coating 122, such that the coating 122 reflects and concentrates solar light rays onto the one or more solar cells 134. Solar light rays either directly strike at least one of the solar cells 134, or impinge on the reflective coating 122 and are thereby reflected, concentrated and collected by the solar cells 134. The reflective coating 122 most typically is disposed on about a bottom half of an exterior surface of the housing, radially from about 90 degrees to about 270 degrees, wherein 0 degrees is the high point of the housing 120, and longitudinally along most or all of the length of the housing 120, thereby creating a wide angle (approximately a 180 degree) concentrator. However, in other embodiments the reflective coating may be disposed on more or less than 180 degrees of the radial surface of the housing 120, or may be disposed on an interior surface of the housing 120.

The reflective coating 122 is most typically a mirror coating, comprising silver or aluminum, which is deposed on a surface of the housing 120 such that solar light rays are directed toward the interior of the housing 120. The reflective coating 122 may be implemented in a series of coatings, comprising one or more of the following: (1) tin chloride (or other compound to bond the reflective coating to the exterior of the housing 120), (2) silver or other reflective material, (3) a chemical activator (or other hardening agent to harden the tin/silver), (4) copper (for durability) and (5) paint (for protecting the coatings from accidental damage).

The absorber assembly 130 generally comprises one or more minichannels 132, and at least one solar cell 134, adjacent to and/or operably attached and/or connected to the minichannels 132. A wide range of conventional solar cells may be used in the absorber assembly 130, including, but not limited to, silicon (Si), copper indium gallium diselenide (CIGS), cadmium telluiride (CdTe), amorphous silicon (aSi), etc.

In some embodiments, solar cells are attached to the one or more minichannels 132 utilizing a conventional high temperature thermally-conductive adhesive (e.g., one or two-part epoxy resins, silicone resins, polyimide resins and/or elastomeric products). In other embodiments, the use of conventional thermally conductive tape (e.g., acrylic tape) may be used for attaching the solar cells to the minichannels. The use of various types and efficiencies of conventional solar cells enables the solar arrays to be tuned for optimal performance, while ensuring that the instant CHP solar collector remains cost-effective. In addition, because the PV solar cells are adjacent and/or attached to the minichannel(s) and are configured to transfer thermal energy to the minichannel(s), there is no need for back insulation, as is required with typical flat plate collectors.

The one or more minichannels 132 may be between about 15 mm and 75 mm in width and between about 1 mm and 6 mm in thickness. The minichannel(s) 132 run longitudinally within the housing 120, and thus, the active heat transfer length of the one or more minichannels is approximately the same or somewhat less than the length of the housing 120. Most typically, the minichannels 132 comprise aluminum, although in some embodiments they may be copper or another metal and/or metal alloy.

Each of minichannels 132 may have between six (6) and twenty-four (24) or more channels, wherein the number of channels is determined, at least in part, by the size of the channel and the desired fluid flow. In minichannels where the channels have a rectangular cross-section, the hydraulic diameter may be between 0.2 mm and 3 mm. However, other cross-sections may be utilized (e.g., circular, square, elliptical, triangular, and/or semicircular). Most typically, the minichannels 132 will have a hydraulic diameter of between 0.75 mm and 2.5 mm.

Fluid flow through the minichannels 132 may range between 0.05 liters/min. (0.013 gpm) and 0.3 liters/min (0.079 gpm), and inlet/outlet temperatures of the fluid may range between 4 degrees C. (39 deg. F.) and 100 deg. C. (212 deg. F.). Most typically, the fluid is water, although other fluids (e.g., ethylene glycol, propylene glycol, acetone, ethanol, methanol, ammonia, etc.) may also be utilized.

In some embodiments, the absorber assembly 130 may be positioned at the lowest point of the housing 120. For example, and as shown in FIG. 1C, for a housing 120 with a circular cross-section, the absorber assembly 130 may be positioned at 180 degrees (wherein 0 degrees is the high point of the housing 120). However, in other embodiments the absorber assembly may be at an alternative radial position.

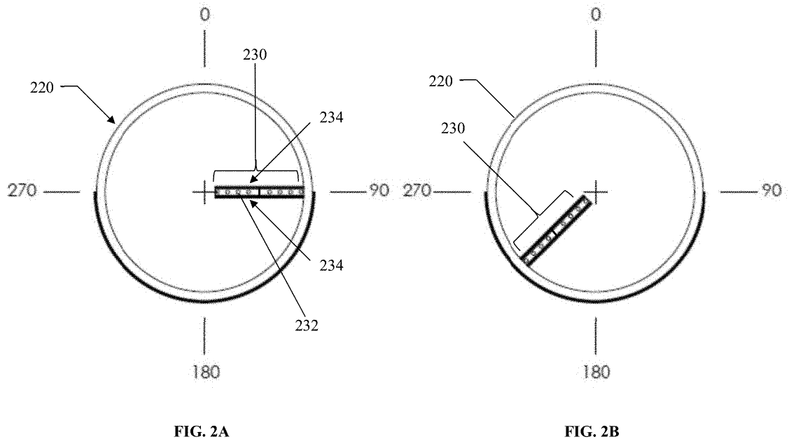

Referring now to FIGS. 2A and 2B, therein are shown alternate absorber assemblies 230, comprising minichannel 232 and solar cells 234, which absorber assembly 230 may be positioned at any radial point between about 90 and 270 (e.g., at 90, 105, 122, 140, 167, 205, 225, etc.) degrees within a housing 220. In FIG. 2A, absorber assembly 230 is positioned at approximately 90 degrees, and in FIG. 2B, absorber assembly 230 is positioned at approximately 225 degrees. Positioning of the absorber assembly is further set forth in discussions that follow.

As indicated, the absorber assembly may comprise one or more minichannels. In an absorber assembly comprising only a single minichannel, fluid flow through the minichannel is single-directional. In other words, the fluid enters the minichannel at one end of the absorber assembly/housing and exits at the opposite end of the absorber assembly/housing. However, in other aspects having at least two minichannels, fluid may enter the absorber assembly at one end, flow through one or more minichannels in one direction, reverse direction and flow through one or more minichannels in the opposite direction, and then exit the absorber assembly/housing at the same end as the fluid entered.

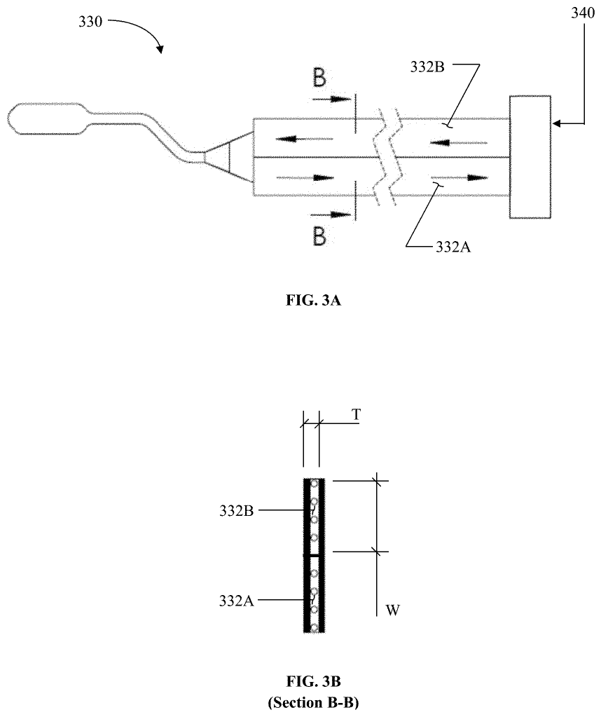

FIGS. 3A and 3B show an absorber assembly 330 having two minichannels 332A and 332B in a “stacked” arrangement (minichannel 332A is adjacent to minichannel 332B along its thinnest edge). In such arrangement, fluid flows in one direction through a first minichannel 332A. The fluid is then directed in the opposite direction and flows through a second minichannel 332B in the opposite direction such that the fluid exits the absorber assembly 330 at the same end that the fluid enters the absorber assembly 330. In some aspects, the fluid may first flow through minichannel 332A and then through minichannel 332B. In other aspects, the flow may be first through minichannel 332B then through minichannel 332A.

In the embodiment shown in FIGS. 3A and 3B, the fluid flow is reversed through bulkhead (manifold) 340. However, in other aspects, U-bends may cause the fluid to flow through minichannels in the opposite direction from the fluid flow through other minichannels. In some aspects, a heat pipe arrangement may be utilized as set forth in detail in the discussions that follow.

Minichannels 332A and 332B, as shown in FIGS. 3A and 3B, are “stacked” such that the area formed by the thickness “T” and the length “L” of each of the minichannels 332A and 332B are adjacent to each other. However, in other instances, minichannels 332A and 332B may be “side-by-side,” such that the area formed by the width “W” and the length “L” of the respective minichannels are adjacent to each other.

### Full Assembly Structure

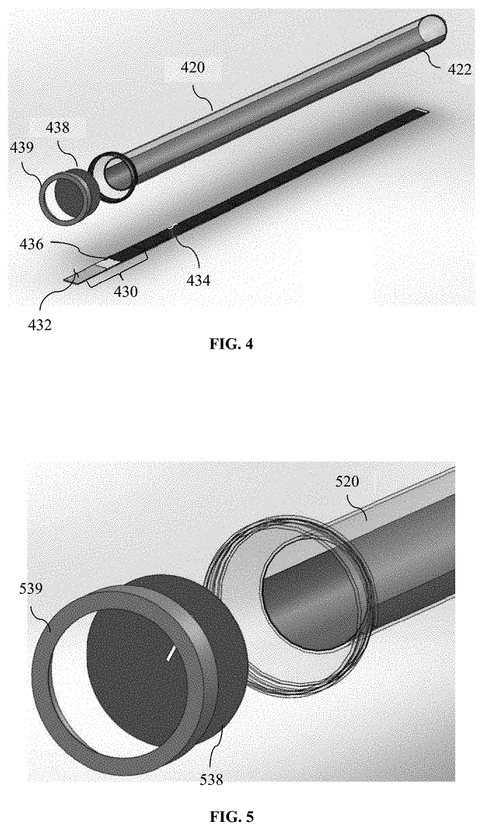

Referring now to FIG. 4, a CHP solar collector comprises: a glass (e.g. borosilicate glass) tube/housing 420 with reflector and/or reflective coating 422, an absorber assembly 430 comprising at least one solar cell 434, minichannel heat transfer element 432, and means of attachment of the solar cell to the heat transfer element (e.g., double-sided heat transfer tape, epoxy or another adhesive, etc.) 436. Most typically, one end of the glass tube 420 is domed. The other of the glass tube/housing may comprise end cap 438 and locking ring 439.

In some embodiments such as the embodiment shown in FIG. 4, the absorber assembly 430 may be replaceable. In such embodiments, a “mason jar” design as shown in FIG. 5, allows the CHP solar collector to be sealed, opened, and then re-sealed. In some embodiments having a replaceable absorber assembly, an end cap may be attached directly to the tube/housing with epoxy or glue. In other aspects, an end of tube/housing 520 may be threaded, and a two-part sealing end cap 538-539 may be utilized wherein a locking ring 539 may be threaded to secure the end cap to the glass tube 520. Due to the low-pressure requirement of the CHP solar collector, such a seal is not as critical as, for example, the typical metal-to-glass seal used in the vacuum industry.

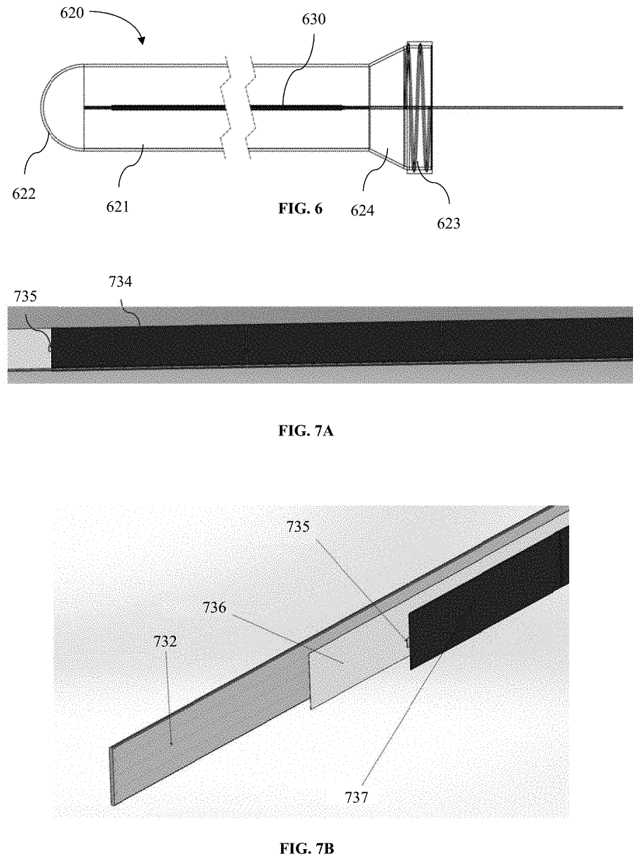

In some aspects, the threaded section of the tube may be manufactured separately and subsequently joined together with a conventional glass tube. For example, the threaded section of the tube may be joined with a conventional glass tube using a taper ground glass joint, with or without plastic (or other type) clips, or other conventional means of making a glass-to-glass connection (e.g., with an epoxy or glue). In other embodiments such as the one shown in FIG. 6, the glass tube 620 may be pre-manufactured as a single piece having a straight section 621, a domed end 622, a threaded section 623, and a tapered section 624. In the embodiment of FIG. 6, the straight section 621 of glass tube may be one diameter (e.g., 70 mm) and the threaded section 623 may be a larger diameter (e.g., 100 mm). In other embodiments, the threaded section and the straight section may have the same diameter, and therefore, no tapered section. The electrical connectors of the solar cell(s) attached to absorber assembly 630 lead out of the tube/housing 620 at the threaded end 623, and a conventional thin wire-to-metal glass seal, or other conventional means of sealing the end 623 of tube/housing 620 around the leads may be utilized. In some embodiments, the end cap (e.g., the end cap 538 of FIG. 5) may be plastic, PLEXIGLAS, or other suitable material and may be made in a single piece, in lieu of the two piece embodiments shown in FIGS. 4 and 5.

### Solar Cell Subassembly

Electrical and mechanical characteristics of the solar cells utilized are critical for a successful implementation of a CHP solar collector. The electrical efficiency of the solar cell significantly affects the overall electrical efficiency of the device.

The mechanical attachment of the solar cell to the, in some instances, aluminum minichannel is dependent on the mechanical strength of the solar cell backing and affects the operating longevity of the CHP solar collector.

In typical embodiments, Interdigitated Back Contact (IBC) solar cells by SUNPOWER may be utilized because of their high efficiency and robustness of the back contacts. In other embodiments, other solar cells may be used. IBC solar cells have a copper backing that is durable making the handling of IBC solar cells comparatively easier than the conventional thin-sliced crystalline solar cells. Such robustness of the solar cell is critical, because in some instances, the solar cells and heat transfer element (most typically an aluminum minichannel) may be assembled using a thermally conductive, electrically insulating tape.

As shown in FIGS. 7A & 7B, IBC solar cells 734 may be interconnected using thin conductors (dogbones) 735. Such thin connectors 735 may be soldered to the back of the solar cell 734 or attached by other conventional means. The solar cells 734 may then be taped or otherwise adhered to the minichannel 732, using for example a thermally conductive, electrically insulating double sided tape 736 such as SHIN-ETSU tape. Use of a tape 736 that is designed to be low emissivity and high strength under extended hours of high temperature application such as tape used for heat sinking for semiconductors is preferred.

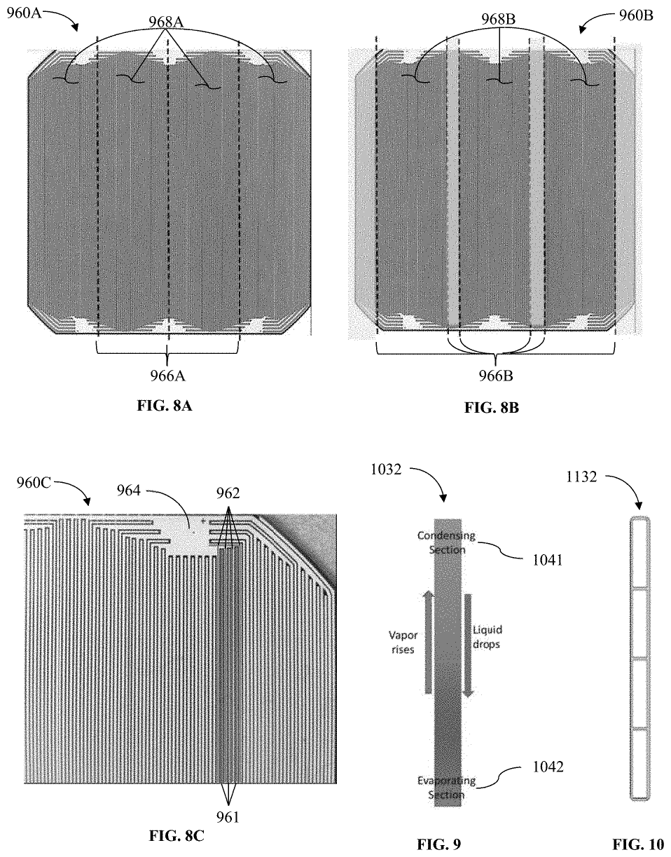

Solar cells may be cut as necessary for attachment to the minichannels. IBC solar cells have a distribution of contacts that enables the solar cell to work even if the fragile silicon wafer on the front of the cell is broken. Referring to FIG. 8C, a portion 960C of an IBC solar cell is shown. The p/n junction is formed between neighboring electrically conducting digits 961 and 962, as shown, respectively, in blue and red in FIG. 8C. Red digits 962 are positive electrodes, and blue digits 961 are negative electrodes. The cell can be cut along the digits and the electrical contacts will remain working, even if the crystalline silicon top is fractured or destroyed. Electrode attaching area 964 is an area of low resistance and may be used for interconnection of cut solar cells. The copper back contact of the IBC solar cells (not shown) provides strong support and good conductivity even after cutting. Thus, IBC solar cells or the equivalent are preferred due to their high efficiency and superior mechanical strength. However, other embodiments of the CHP solar collector may use other types of solar cells.

At least two different cutting schemes may be utilized to cut the solar cells as necessary to fit the minichannels. These schemes are shown in FIGS. 8A & B, wherein the dashed lines 966A and 966B of, respectively, solar cells 960A and 960B represent cut lines. As can be seen in FIG. 8A, three (3) parallel cuts are made at cut lines 966A such that the IBC solar cell 960A is divided in four (4) substantially equal portions 968A. The scheme shown in FIG. 8A lends itself well to mass manufacturing of CHP solar collectors utilizing conventional wafer dicing technology. Alternatively, and as shown in FIG. 8B, six (6) parallel cuts 966B may be made such that the IBC solar cell 960B is divided into three (3) substantially equal portions 968B. Other cutting schemes which retain the functionality of the solar cells and provide for the proper fit of the solar cells to the minichannels may also be utilized.

### Heat Transfer Configurations

At least two heat transfer configurations may be utilized for transferring solar energy to the fluid flowing through the minichannels: (1) the heat pipe (HP) configuration; and (2) direct flow (DF) configuration.

Heat Pipe (HP) Configuration

A heat pipe is commonly regarded as the “super conductor” for a heat transfer element. The temperature drop between the condensing and the evaporating sections of a heat pipe is typically below 2° C. and serves as a preferred heat transfer element for extracting heat from the solar cells. In some embodiments, a wick inside the heat pipe facilitates the circulation of the working fluid. However, in preferred embodiments and to reduce the cost, a gravitational heat pipe is utilized.

Referring now to FIG. 9, a schematic of a gravitational heat pipe 1032 is shown, comprising a condensing section 1041 and an evaporating section 1042. In the condensing section 1041, the condensed liquid (working fluid) drops to the bottom of the heat pipe. In the evaporating section 1042, the liquid that has been evaporated rises. Due to the low pressure inside of the heat pipe 1032, the working fluid (e.g., water, acetone, etc.) evaporates and extracts heat from the evaporation section. The vapor then rises toward the top of the heat pipe 1032 and releases its heat to the nearby environment, thereby returning to a liquid. The liquid then drops or “creeps” back toward the bottom of the heat pipe 1032 as a result of gravity.

In some embodiments, the heat pipe may be constructed of aluminum and/or copper and the working fluid may be water, acetone, ethanol, methanol, ammonia, etc. In embodiments utilizing acetone under normal working conditions, the heat pipe may transfer a finite amount of heat until such time as the working fluid/acetone is evaporated dry.

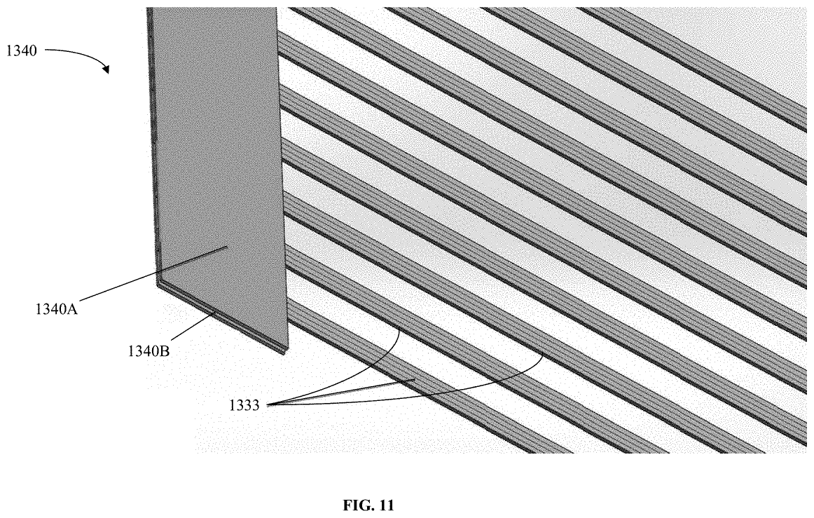

Typically, the heat pipe is of a length (e.g., 2000 mm) such that a typical shipping box may be utilized for transporting the heat pipe, and that which may be manufactured utilizing a conventional aluminum multi pore extrusion (MPE) process of standard size. A typical cross section of a heat pipe 1132 according to an embodiment is shown in FIG. 10. Additionally, in embodiments utilizing a manifold, the size of the heat pipe may be dependent on the connection configuration between the condenser and the manifold.

In embodiments having a mid-temperature operating range of 0° C. to 120° C., the commonly used heat pipe heat transfer fluids are water, acetone, ammonia, ethanol, methanol and heptane.

In some instances (e.g., a heat pipe constructed of copper) water may be a preferable heat transfer fluid due to the high effective conductivity of the heat pipe corresponding to a low temperature drop. In some instances, ammonia may be utilized because it is similar to water in heat transfer characteristics, but in such instances, the heat pipe must be highly pressurized. Acetone is also a preferred heat transfer fluid because of its heat transfer properties.

The choice of a working fluid is dependent on the ambient operating conditions. For example, limitations may occur with melting of water at low temperatures, while at typical operating conditions, acetone does not freeze. Hence in some instances having low operating temperatures, a mixture of water and acetone may be a preferred fluid. In instances using aluminum as the material for construction of the heat pipe, acetone is the preferred working fluid.

Manifold Design of Heat Pipe

Referring now to FIG. 11, in embodiments having a plurality of heat pipes 1333, a manifold 1340 may be utilized to provide for return of the working fluid through the heat pipe. As shown in FIG. 11, manifold 1340 may comprise two manifolds portions 1340A and 1340B, which sandwich the condenser section (not shown) of the heat pipes 1340 from both the front and the back. In some instances, the manifold 1340 may be 100 mm wide minichannels, because such minichannels are a standardized size. In other instances, other manifold widths may be utilized. Because the condenser section of the heat pipe is flat instead of a conventional cylindrical shape, minichannels achieve a lower temperature drop between the working fluid and the walls of the manifold. In preferred embodiments, the width of the manifold is selected such that, the length of the condenser is in full contact with the manifold surface.

Thermal Analysis of Heat Pipe Manifold

As indicated above, in preferred embodiments having a 100 mm wide manifold, the length of the condenser is in full contact with the manifold surface. In embodiments in which a part of the condenser surface length is not in contact with the manifold surface, the heat exchange surface between the condenser and the manifold is reduced. This reduction in contact surface area reduces the heat received by the manifold material and, correspondingly, the total heat received by the working fluid. A wider manifold, however, will increase the volume and the weight which, in turn will increase production, handling and transportation costs. A wider manifold will also detrimentally allow a larger heat loss to the environment along the gap created by the additional width. In some embodiments, the depth of the flow depth in channels in the manifold may be 1.5 mm. In other embodiments, other depth of channels may be utilized.

The heat absorbed by the working fluid is given by the formula Q=\dot{m}*Cₚ*ΔT where Q is the total heat received, \dot{m} is mass flow rate, Cₚ is the specific heat of the fluid, and *ΔT is the temperature difference between the inlet and the outlet of the heat receiving contact region.

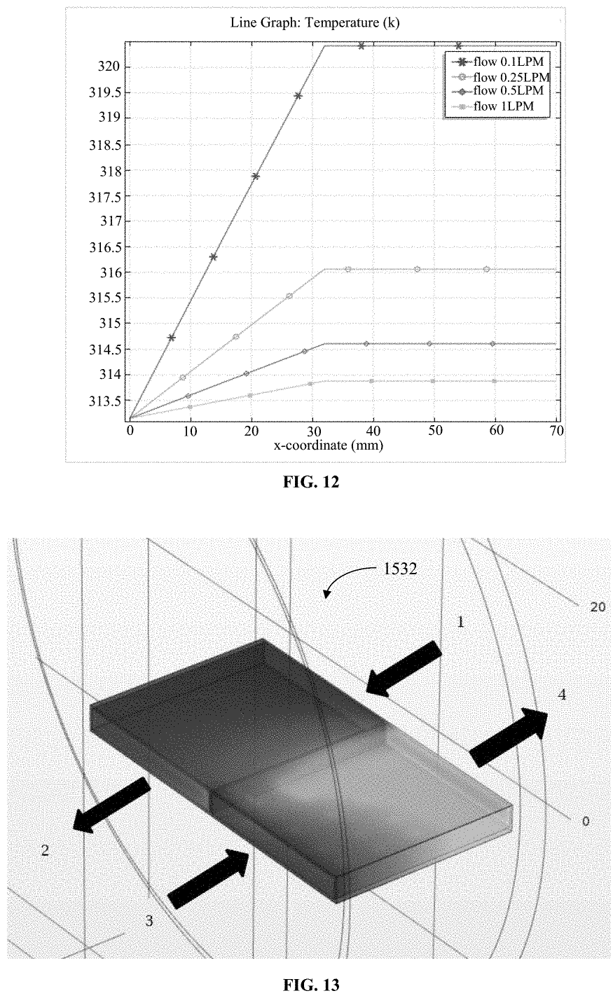

As can be seen in FIG. 12, a higher flow rate decreases the net temperature gain by the working fluid and reducing the flow rate increases the net temperature gain. Also as indicated in FIG. 12, a linear relationship is established along the heat receiving region equal to a condenser width of 32 mm. Based on the flow rate and heat transfer coefficient, the inside surface temperature of the manifold is determined. Thus, depending on the heat received by the manifold surface and the flow rate of the fluid to be heated, the number of heat pipe arrays to achieve the target fluid temperature is determined.

For example, for a flow rate of 0.5 l/min with a gain of 1.45° C., at least ten heat pipe arrays in series is required. As an additional example, for a flow rate of 2.5 l/min with a gain of 2.9° C., five heat pipe arrays in series is sufficient. The net water temperature gain depends on the flow rate and the heat received. These are just examples, and various different combinations of flow rates, fluid temperatures, and number of heat pipes may be utilized.

Direct Flow (DF) Configuration

In some embodiments, a direct flow (DF) configuration may be utilized. The direct flow configuration provides performance similar to the performance of a heat pipe. As shown in FIG. 13, the working fluid flows into minichannel 1532 from arrow 1, and exits minichannel 1532 at arrow 2. The flow of the working fluid is then reversed/redirected 180° (e.g., through a U-shape bend, or a manifold, not shown) to point 3 and will exit at arrow 4. Because the concentration of light is mostly between point 3 and 4, the working fluid heats up more in the section (between arrows 3 and 4) than it does in the first section (between arrows 1 and 2). As a result of the excellent heat transfer of the thin walled (and in certain embodiments), aluminum minichannel, heat is easily transferred to the minichannel, thereby cooling down the solar cells and improving the operating efficiency of the cells.

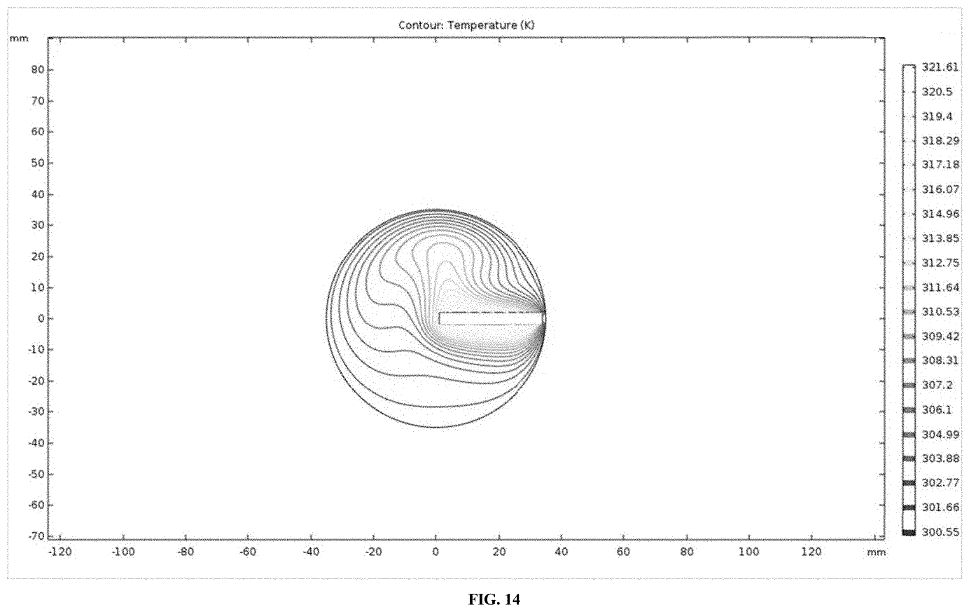

Referring now to FIG. 14, therein is shown a temperature distribution of the direct flow configuration with the absorber in the 90° position. The distribution of FIG. 14 demonstrates that the surface temperature of the minichannel in this position is almost uniform, and a natural convection simulation for argon gas inside the housing/tube demonstrates less heat loss compared to other solar collector arrangements. With the minichannel (absorber) positioned at 3 o'clock (horizontal) the temperature increase is largely concentrated around the minichannel rather than the entire volume of the housing, providing for increased performance of the CHP solar collector.

Typically, at the heating up/transitional stage of the solar collector, the maximum temperature on the surface of the minichannel is 21.55° C., and the lowest temperature in the working fluid is 20.25° C. Thus, the temperature difference caused by heat transfer on the surface of the direct flow minichannel is less than 1.5° C. Given a maximum of 10° C. for total temperature drop from the solar cell to the minichannel working fluid, the heat transfer of the minichannel in a direct configuration is adequate. Thus, a direct flow configuration may be used in some embodiments of the CHP solar collector.

Absorber Assembly Positioning

As indicated above, the absorber assembly may be positioned within the housing/tube at any radial point between about 90° and 270°, wherein 0° is the highest point (12 o'clock position) of the housing/tube. In preferred embodiments, the absorber is positioned at 90° (3 o'clock), 180° (6 o'clock), or 135° (halfway between the 3 o'clock position and the 6 o'clock position, i.e. the 4:30 position).

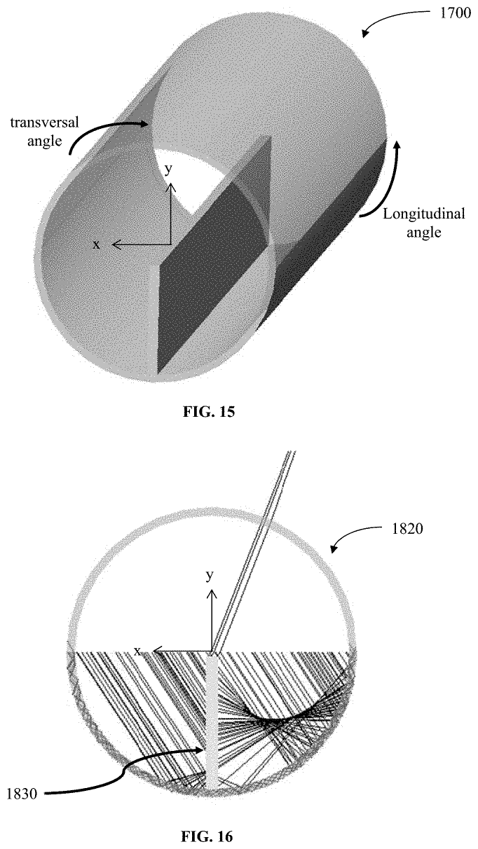

To determine an optimal absorber position, a simulation using LIGHTTOOLS was performed for each of the three preferred absorber positions (i.e., 90°, 135° and 180°) using a 200 mm section of a single CHP solar collector. In FIG. 15, transversal and longitudinal angles of CHP solar collector 1700 are shown. The incident angle of solar rays is restricted to the x, y plane, as shown in FIGS. 15 and 16, which is the cross-sectional plane of the solar collector. In FIG. 16, the absorber assembly 1830 is shown in the 180°/6 o'clock position inside of housing/tube 1820. The incident angle is 33 degrees at about 10 o'clock in the morning for the equinox day. The solar collector is tilted longitudinally according to the local latitude. FIG. 16 shows light ray tracing under a transversal angle analysis of the CHP solar collector.

Based on the transversal angle analysis of FIG. 16, radiation density at the absorber is determined. Referring now to FIG. 17, therein is shown the solar radiation density in W/mm² on the left side of the absorber 1830 of FIG. 16. It should be noted that for the left side of the absorber 1830, the y positive direction in FIG. 17 is the y negative direction in the 3D model of FIG. 16.

The results of the optical simulation were also recorded as the cell data shown in Table 1 below, and the total radiation is verified with the absorbed watts as determined by the LIGHTTOOLS software analysis.

TABLE 1

| metric | metric | iluminance | | | | | | | |
|---|---|---|---|---|---|---|---|---|---|
| min [symbol] bound | min [symbol] bound | max [symbol] bound | max [symbol] bound | [symbol] | [symbol] | [symbol] | W/mm [symbol] | | |
| −100 | −1 [symbol] | 100 | 1 [symbol] | | | | | | |
| 0.000128259 | 0.00012759 | 0.000125125 | 0.000127588 | 0.000123924 | 0.0001188 [symbol] 9 | 0.00011 [symbol] | 0.000124 | 0.000123 | 0.00011 [symbol] |
| 0.000173335 | 0.00017994 | 0.000157787 | 0.000169015 | 0.000171177 | 0.000171514 | 0.00017 [symbol] | 0.000175 | 0.000175 | 0.000172 |
| 00027757 [symbol] | 0.00017744 | 0.000170823 | 0.00016 [symbol] | 0.000175723 | 0.0002 [symbol] | 0.000 [symbol] 84 | 0.0001 [symbol] | 0.000132 | 0.00013 |
| 0.000110519 | 0.00010991 | 0.000197042 | 0.00010359 | 0.000107344 | 0.000110 [symbol] | 0.000114 | 0.000112 | 0.000111 | 0.00011 |
| 4.58E−05 | 4.49E−05 | 4.7 [symbol] E−05 | 4.76E−05 | 4.64E−05 | 4. [symbol] E−05 | 4.73E−05 | 4.68E−05 | 4.47E−05 | 4.4 [symbol] E−05 |
| 4. [symbol] E−05 | 4.51E−05 | 4.7 [symbol] E−05 | 4.71E−05 | 4.56E−05 | 4. [symbol] E−05 | 4.78E−05 | 4.78E−05 | 4.49E−05 | 4.43E−05 |
| 4. [symbol] E−05 | 4. [symbol] E−05 | 4.75E−05 | 4.53E−05 | 4.59E−05 | 4.77E−05 | 4.94E−05 | 4. [symbol] E−05 | 4.71E−05 | 4.7 [symbol] E−05 |
| 4. [symbol] E−05 | 4. [symbol] E−05 | 4.77E−05 | 4.44E−05 | 4.55E−05 | 4.93E−05 | 4.99E−05 | 4.59E−05 | 4.79E−05 | 5. [symbol] E−05 |
| 4. [symbol] E−05 | 4. [symbol] E−05 | 4.66E−05 | 4.51E−05 | 4.75E−05 | 4.97E−05 | 4.7 [symbol] E−05 | 4.5 [symbol] E−05 | 4.75E−05 | 4.97E−05 |
| 4. [symbol] E−05 | 4.7 [symbol] E−05 | 4.58E−05 | 4.48E−05 | 4. [symbol] E−05 | 4.92E−05 | 4. [symbol] E−05 | 4.75E−05 | 4.81E−05 | 4. [symbol] E−05 |
| 4. [symbol] E−05 | 4. [symbol] E−05 | 4.57E−05 | 4.45E−05 | 4.57E−05 | 4.88E−05 | 4.94E−05 | 4. [symbol] E−05 | 4.73E−05 | 4.67E−05 |
| 5.00E−05 | 5.00E−05 | 4.62E−05 | 4.46E−05 | 4. [symbol] E−05 | 4. [symbol] 6E−05 | 4. [symbol] 4E−05 | 4.55E−05 | 4.65E−05 | 4.23E−05 |
| 5.15E−05 | 5. [symbol] E−05 | 4.53E−05 | 4.46E−05 | 4.26E−05 | 4. [symbol] E−05 | 4.31E−05 | 4. [symbol] E−05 | 4. [symbol] E−05 | 5. [symbol] E−05 |
| 5. [symbol] 5E−05 | 4.22E−0E | 4.53E−05 | 4.32E−05 | 4. [symbol] E−05 | 4.54E−05 | 4.63E−05 | 4.21E−05 | 4.91E−05 | 4.9 [symbol] E−05 |
| 5. [symbol] E−05 | 4. [symbol] E−05 | 4.53E−05 | 4.5 [symbol] E−05 | 4.4 [symbol] E−05 | 4.17E−05 | 4.37E−05 | 4. [symbol] E−05 | 4.65E−05 | 4.39E−05 |
| 5.24E−05 | 4. [symbol] 4E−05 | 4.42E−05 | 4.52E−05 | 4.79E−05 | 4.4 [symbol] E−05 | 4.46E−05 | 4.51E−05 | 4.51E−05 | 4. [symbol] E−05 |
| 4. [symbol] E−05 | 4.29E−05 | 4.39E−05 | 4.5 [symbol] E−05 | 4. [symbol] E−05 | 4.76E−05 | 4.79E−05 | 4.51E−05 | 4.50E−05 | 4.72E−05 |
| 4.01E−05 | 3. [symbol] E−05 | 4.37E−05 | 4.54E−05 | 4.51E−05 | 4.54E−05 | 4. [symbol] E−05 | 4.76E−05 | 4.50E−05 | 5.11E−05 |
| 4.25E−05 | 4. [symbol] E−05 | 4.27E−05 | 4.53E−05 | 4.5 [symbol] E−05 | 4.45E−05 | 4.4 [symbol] E−05 | 4.71E−05 | 4. [symbol] E−05 | 4.78E−05 |
| 4.70E−05 | 4.48E−05 | 4.33E−05 | 4.3 [symbol] E−05 | 4.31E−05 | 4.37E−05 | 4.53E−05 | 4.55E−05 | 4.53E−05 | 4.5 [symbol] E−05 |
| 4.81E−05 | 4.33E−05 | 4.53E−05 | 4. [symbol] E−05 | 4. [symbol] 3E−05 | 4.51E−05 | 4.77E−05 | 4. [symbol] E−05 | 4.4 [symbol] E−05 | 4.60E−05 |

| | | | | | | | | | |
|---|---|---|---|---|---|---|---|---|---|
| 0.000118 | 0.000125 | 0.000125 | 0.000122 | 0.000122 | 0.000124 | 0.000127 | 0.000129 | 0.00025 [symbol] | |
| 0.00017 | 0.00017 | 0.000171 | 0.00017 [symbol] | 0.000175 | 0.000173 | 0.0001 [symbol] | 0.000165 | 0.0003597 | |
| 0.00012 | 0.000175 | 0.000175 | 0.00015 | 0.000355 | 0.000182 | 0.000171 | 0.000162 | 0.0003715 | |
| 0.000114 | 0.000112 | 0.000111 | 0.000119 | 0.000117 | 0.000113 | 0.000105 | [symbol] E−05 | 0.002307 | |
| 4. [symbol] 9E−05 | 5.27E−05 | 5.18E−05 | 4.55E−05 | 4.51E−05 | 4. [symbol] E−05 | 4.43E−05 | 4.41E−05 | 0.000 [symbol] | |
| 4. [symbol] E−05 | 4. [symbol] E−05 | 4.78E−05 | 4.4 [symbol] E−05 | 4.52E−05 | 4. [symbol] E−05 | 4. [symbol] E−05 | 5.05E−05 | 0.000577 | |
| 4.87E−05 | 4.78E−05 | 4. [symbol] E−05 | 4.33E−05 | 4. [symbol] E−05 | 4.57E−05 | 4. [symbol] E−05 | 4. [symbol] E−05 | 0.000575 | |
| 5. [symbol] E−05 | 4.82E−05 | 4.77E−05 | 4.23E−05 | 4. [symbol] E−05 | 4. [symbol] E−05 | 4. [symbol] E−05 | 4.29E−05 | 0.000551 | |
| 4. [symbol] E−05 | 4.75E−05 | 5. [symbol] E−05 | 5. [symbol] E−05 | 4.4 [symbol] E−05 | 4. [symbol] E−05 | 4.37E−05 | 4. [symbol] E−05 | 0.0005 [symbol] | |
| 4.44E−05 | 4.41E−05 | 4.65E−05 | 4.77E−05 | 4. [symbol] E−05 | 4. [symbol] E−05 | 4.75E−05 | 4.48E−05 | 0.000 [symbol] | |
| 4.31E−05 | 4.15E−05 | 4.36E−05 | 4.70E−05 | 4.80E−05 | 4.7 [symbol] E−05 | 4. [symbol] E−05 | 4. [symbol] E−05 | 0.000966 | |
| 4.6 [symbol] E−05 | 4.24E−05 | 4.40E−05 | 4.51E−05 | 4.57E−05 | 4.31E−05 | 4.25E−05 | 4. [symbol] E−05 | 0.000965 | |
| 4.9 [symbol] E−05 | 4. [symbol] E−05 | 4.47E−05 | 4.55E−05 | 4. [symbol] E−05 | 4.45E−05 | 4.4 [symbol] E−05 | 4. [symbol] E−05 | 0.000922 | |
| 4. [symbol] E−05 | 4.68E−05 | 4.50E−05 | 4.59E−05 | 4.74E−05 | 4.7 [symbol] E−05 | 4.57E−05 | 4.42E−05 | 0.000925 | |
| 4.49E−05 | 4. [symbol] E−05 | 4.37E−05 | 4. [symbol] E−05 | 4.78E−05 | 4.69E−05 | 4.48E−05 | 4.31E−05 | 0.00097 | |
| 4. [symbol] E−05 | 4.93E−05 | 4.37E−05 | 4.53E−05 | 4.33E−05 | 4. [symbol] E−05 | 4. [symbol] E−05 | 4.41E−05 | 0.00097 | |
| 4.87E−05 | 4.7 [symbol] E−05 | 4. [symbol] E−05 | 4.24E−05 | 4.4 [symbol] E−05 | 4. [symbol] 2E−05 | 4.79E−05 | 4.57E−05 | 0.000575 | |
| 5.07E−05 | 4. [symbol] E−05 | 4. [symbol] E−05 | 4. [symbol] E−05 | 4. [symbol] E−05 | 4.70E−05 | 4.55E−05 | 4.52E−05 | 0.000575 | |
| [symbol] E−05 | 5.10E−05 | 5.21E−05 | 4.99E−05 | 4.4 [symbol] E−05 | 4.33E−05 | 4.50E−05 | 4.58E−05 | 0.0009 [symbol] | |
| 5.42E−05 | 4.74E−05 | 5.03E−05 | 4. [symbol] E−05 | 4.48E−05 | 4. [symbol] E−05 | 4.35E−05 | 4. [symbol] E−05 | 0.00095 [symbol] | |
| 4.57E−05 | 4.25E−05 | 4.43E−05 | 4.74E−05 | 4. [symbol] E−05 | 5.15E−05 | 5.15E−05 | 4. [symbol] E−05 | 0.00096 | |
| | | | | | | | | 0.52795 | 0.417905242 |

[symbol]

indicates data missing or illegible when filed

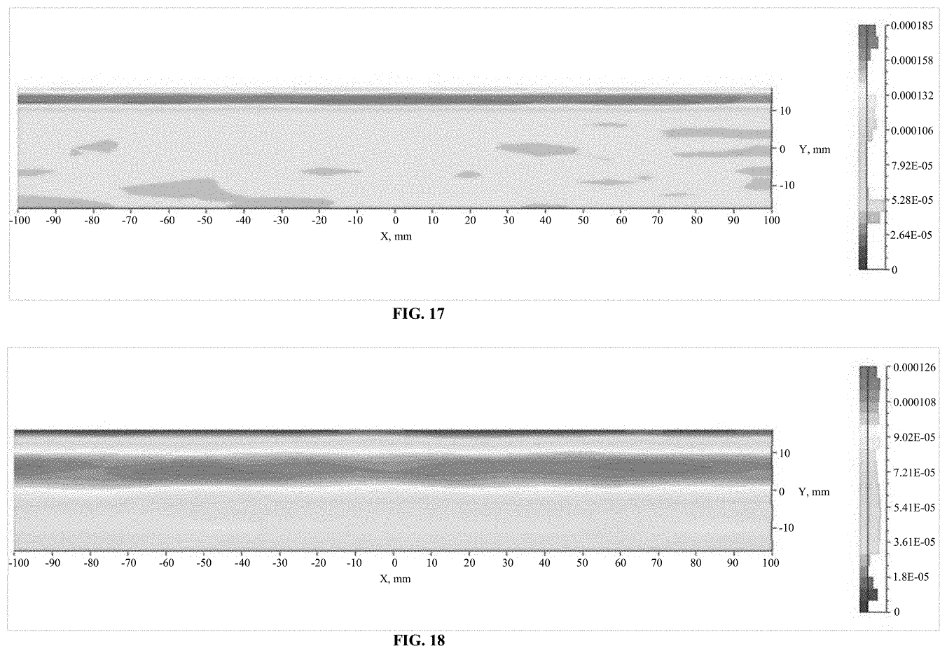

Similar to FIG. 17, FIG. 18 shows the solar density on the right side of the absorber. Compared to the left side, the maximum of the distribution on the right side is lower. However, the width of the concentrated area is wider. Consequently, the distribution of the power density is roughly the same in the axial (or longitudinal) direction; however, the distribution varies up to 2.4 times the concentration in the transversal direction.

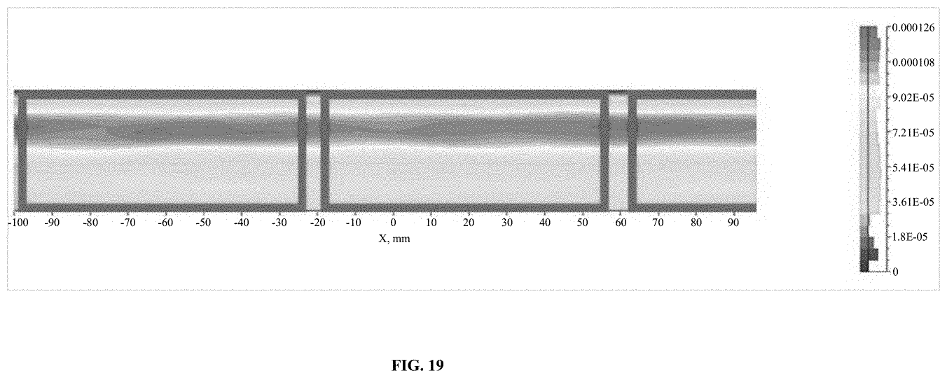

Referring now to FIG. 19, therein is shown a radiation map of an arrangement of solar cells along the longitudinal axis of an absorber in a CHP solar collector. As indicated, the power density is roughly the same along the longitudinal direction. Thus, FIG. 19 shows a radiation distribution similar to the radiation mapping of FIG. 19, but also shows an arrangement of solar cells in the longitudinal direction.

### Hot Spot Effect and Mitigation

The result of ray tracing indicates that the effect of hot spots can be mitigated. The hot spot effect is more significant with the 6 o'clock absorber configuration than the 3 o'clock configuration. However, if the solar cells are connected in series along the axial (longitudinal direction), the mismatching of the current among the solar cells is minimized. The concentration of the solar radiation at hot spots is limited (typically less than 3 times), and high concentration of sunlight only happens during the sunrise and sunset hours for the 180° (six o'clock) absorber configuration. The horizontal, 90° (3 o'clock) configuration of the receiver does not suffer from any high concentrations/hot spots, and thus, the hot spot effect is not a concern for the 90° configuration.

### Ray Tracing at Different Sun Positions

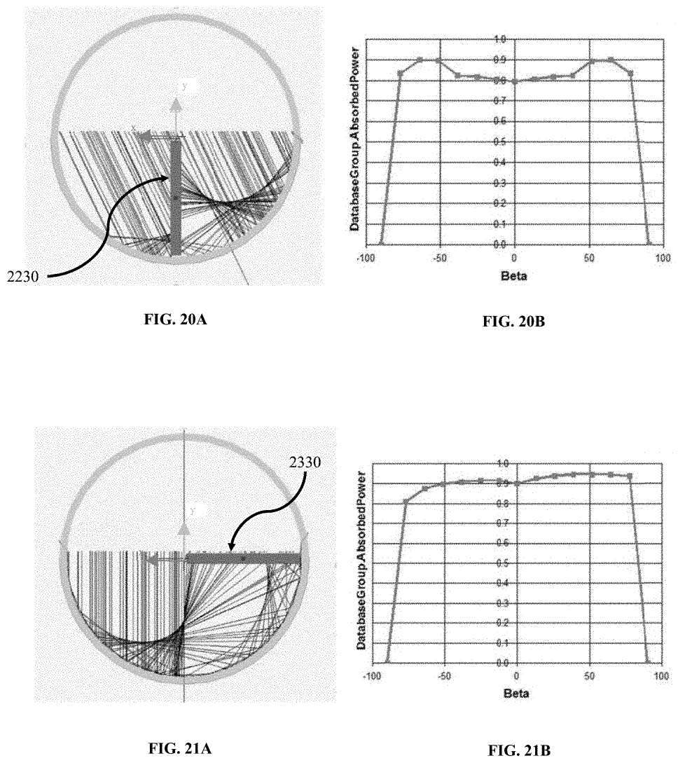

Because of the different positions of the sun due to daily and seasonal changes, a sensitivity simulation of the CHP solar collector was performed. The simulation performed was based on a 92% reflectivity for the reflective coating/mirror (see e.g., reflective coating 122 of FIG. 1) to determine the overall efficiency, and thus, the optimal position of the absorber in the CHP collector. FIG. 20A shows absorber 2230 in the 180° position. FIG. 21A shows the absorber 2330 in the 90° position, and FIG. 22A shows the absorber 2430 in the 135° position. FIGS. 20B, 21B and 22B show the corresponding power curves for the three absorber positions.

The overall efficiency of the three configurations according to the sensitivity analysis shows that the 90°, horizontally positioned (3 o'clock) absorber configuration has slightly better optical efficiency than the 135° absorber configuration, with the vertically positioned receiver 180° (6 o'clock) configuration being the least efficient. The fact that the 90° configuration has the highest efficiency is logical because at least one side of the horizontally positioned absorber will never suffer from a lower reflectivity of the mirror.

### Thermal Results for CHP Solar Collector

In a preferred embodiment of the CHP solar collector, the housing/tube is filled with argon gas. Use of argon gas, in lieu of air or nitrogen, reduces the free convection heat loss by about one third (⅓). Finite element analysis (FEA) was performed for free convection using COMSOL. The free convection modeling is based on two different fluids, namely, air and argon, two different absorber configurations, 3 o'clock and 6 o'clock, and wind cooling on the outside surface of the tube. The fluid mechanic analysis of air stream circulation is performed first.

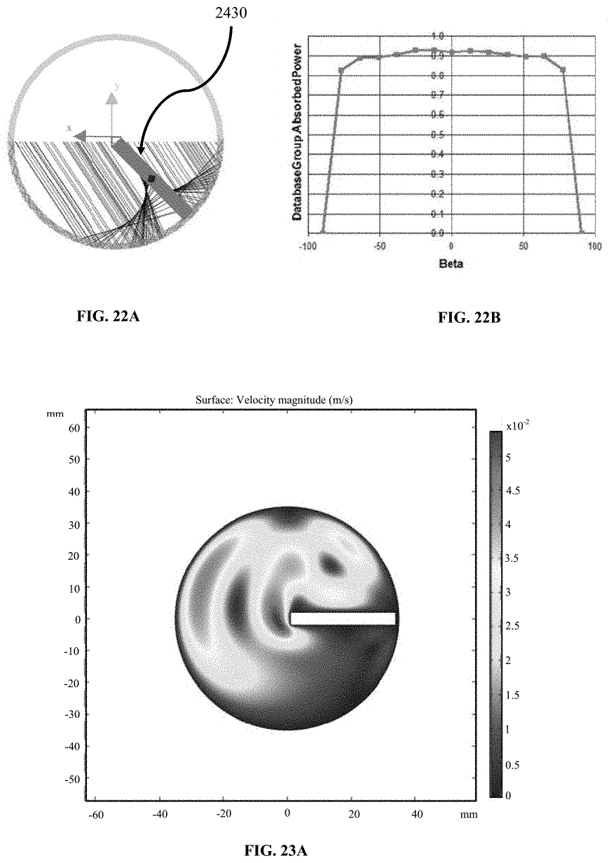

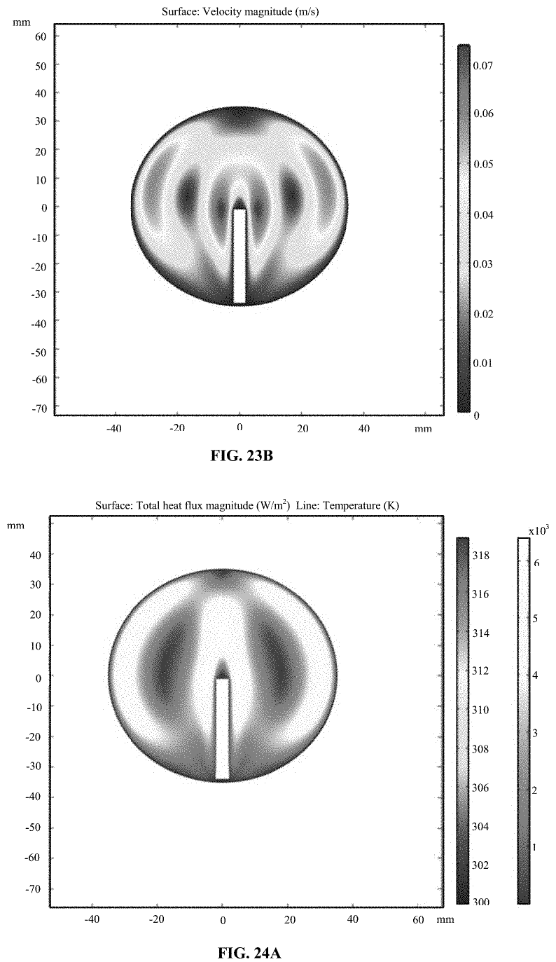

As shown in FIGS. 23A and 23B, the highest velocity of the air happens at left edge of the absorber in the 90° configuration and the air pattern is asymmetric. However in the 180° (6 o'clock) configuration, the air velocity field is symmetric and there is airflow all around the tube, causing additional heat loss. Also, as shown in both FIGS. 23A and 23B, the low Rayleigh number indicates the airflow laminar, which laminar airflow causes much less heat transfer compared to turbulent airflow.

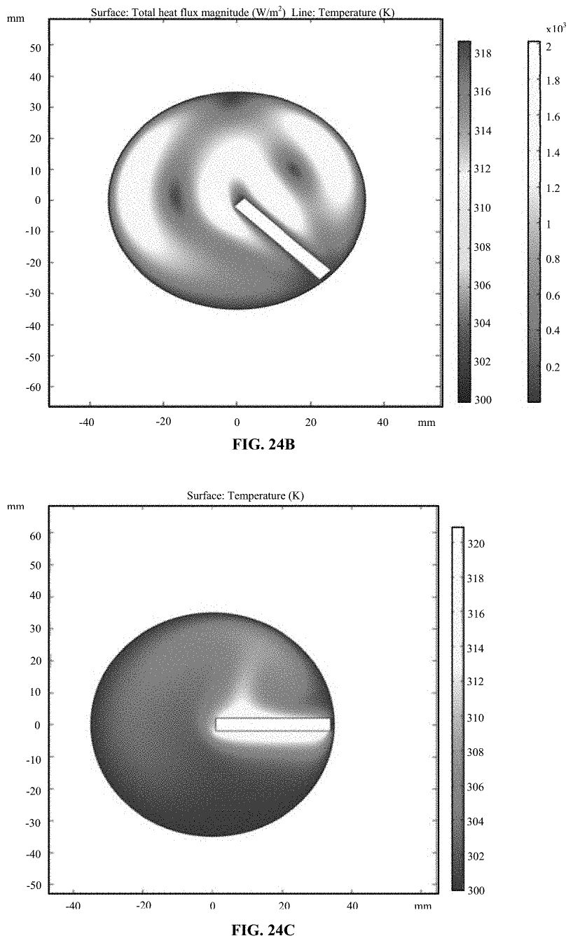

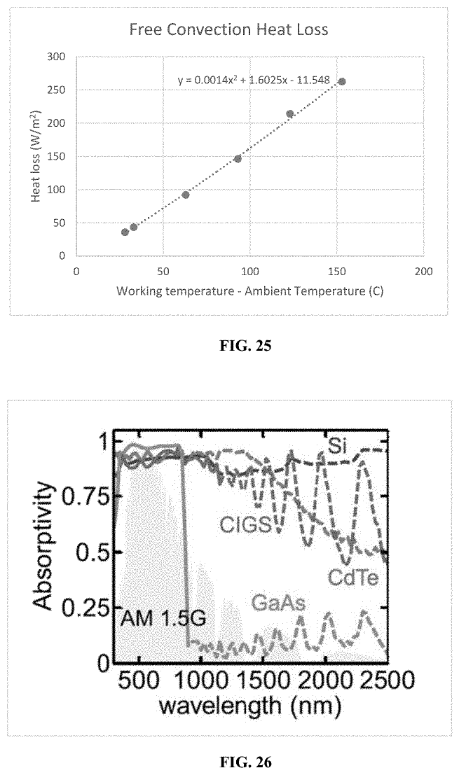

Subsequently, a heat transfer analysis was performed to determine the free convection heat loss in the tube. The results of the heat transfer analysis based on the three preferred configurations for the absorber are shown in FIGS. 24A-C. Due to the buoyancy of hot air, both the 180° and 135° degree configurations allow the natural convection to produce circulation of the air. In contrast, the 90° configuration has 23% less convection heat loss compared to the other (180° and 135°) configurations. Therefore, analysis of convective heat loss as a function of working temperature for the 90° configuration was analyzed, and the results are shown in FIG. 25.

The free convection within the collector remains laminar up to an absorber temperature 180 degree Celsius above the ambient temperature, and the heat loss rises in a linear fashion according to such a temperature difference. Thus, convection heat loss can be well controlled with an appropriate gas (e.g. argon) in the collector housing and an effective configuration of the receiver (e.g., 90°). Because the convection heat loss can be controlled, the radiative heat loss becomes the main factor controlling the thermal efficiency of the absorber.

### Heat Loss Due to Radiation

The analysis of the radiation heat loss significantly impacts the performance of the CHP solar collector due to the drastic increase of radiant heat loss at higher working temperature, which heat loss effectively determines the stagnation temperature of the absorber. The results of a solar cell emissivity analysis by Xingshu Sun, et al., “Optics-Based Approach to Thermal Management of Photovoltaics: Selective-Spectral and Radiative Cooling,” IEEE Journal of Photovoltaics (Vol. 7, Issue 2, March 2017) (“Radiative Cooing”) performed on typically available solar cells is shown in FIG. 26.

Among the analyzed solar cells, only the silicon (Si) solar cell can be directly exposed to the environment, whereas solar cells manufactured from other materials will require topping layers and/or coatings. Consequently, while Si solar cells may act as the emitting surface, other thin film solar cells (e.g., GaAs, CdTe, CIGS) have emissivities which are determined by their topping layers/coatings. Such topping/coating layer(s) may be either a Transmissive Conductive Oxide (TCO) layer or glass. Consequently there are three choices for calculating the radiation loss: (1) silicon; (2) TCO; or (3) glass.

The emissivity of silicon is high for most of the commercially available mono- and multi-crystalline solar cells. This is due to the high absorptivity of the sub-bandgap photons, caused by the back reflector properties, or the doping of the bottom layer of the silicon cells. This will also result in a high radiative heat loss and low stagnation temperature.

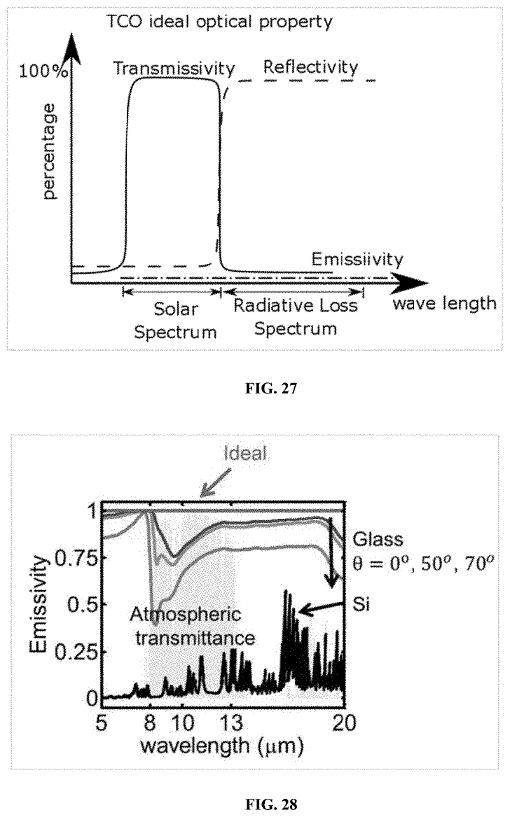

In some embodiments, existing glass topping solar cells may be removed to expose the TCO layer of the thin film solar cells or, alternatively, TCO may be deposited on silicon solar cells (e.g., Panasonic Heterojunction with Intrinsic Thin layer (HIT) cells) to reduce the emissivity. Because the high infrared (IR) reflectivity of a TCO topping layer can reduce the emissivity by reflecting back the infrared emission from the solar cell, using a TCO as the top layer increases the thermal efficiency, which also increases the stagnation temperature of the solar collector. FIG. 27 (by Mikio Taguchi, et al., “24.7% Record Efficiency HIT Solar Cell on Thin Silicon Wafer”, IEEE Journal of Photovoltaics (Vol. 4. Issue 1, January 2014) shows the ideal optical properties of TCO as a function of wavelength. Alternating the high transmissivity and reflectivity of the TCO topping layer results in a low emissivity of the solar cell across the spectrum of wavelengths.

In contrast, the emissivity of glass is high, resulting in high radiation loss and low thermal efficiency. However, the stagnation temperature of the solar collector utilizing glass will be low, allowing simpler adhesive mechanisms for solar cells. Typical solar cells using glass covers can be CIGS, CdTe or GaAs thin film solar cells. FIG. 28 shows the emissivity of glass at different angles for long wavelengths. The shaded area of FIG. 28 is the emissivity spectrum.

### Heat Transfer

The horizontal (90°) configuration was utilized to evaluate stagnation temperature due to its lower convective heat loss. If there is no radiation heat loss, the base line convection loss will cause the CHP solar collector to stagnate at a temperature much higher than 150° Celsius.

As the emissivity of the solar cell is varied, the thermal performance changes. To achieve better thermal efficiency, the higher stagnation temperatures must be mitigated. The thermal performance/stagnation temperature is mostly affected by the heat loss, which is determined by the solar cell topping layer/coating. Ideally, the stagnation temperature should be below 150° C. because at higher temperatures, the attachment for the solar cell may be affected. For example, the shear strength of double sided acrylic tape decreases as temperature increases (see e.g., http://www.shinetsusilicone-global.com/products/function/heat/index.shtml).

### CHP Solar Collector Performance

The performance of the three preferred device configurations (90°, 135° and) 180° is shown below in, respectively, Tables 2, 3 and 4.

TABLE 2
90 Degree (3 O’clock) Configuration

| Climate | | | | | | Thermal | electrical |
|---|---|---|---|---|---|---|---|
| Zone | | GHI(KWHr/day/ | Optical | Thermal | Electrical | output(KWhr/day/ | output(KWhr/day/ |
| number | Area name | m2) | efficiency | efficiency | efficiency | m2) | m2) |
| 1 | Arcata | 3.93 | 0.84 | 0.24 | 0.2 | 0.95 | 0.66 |
| 2 | Santa Rosa | 4.64 | 0.84 | 0.31 | 0.2 | 1.43 | 0.78 |
| 3 | Oakland | 4.63 | 0.84 | 0.31 | 0.2 | 1.42 | 0.78 |
| 4 | San Jose | 4.96 | 0.84 | 0.33 | 0.2 | 1.65 | 0.84 |
| 5 | Santa Maria | 5.19 | 0.84 | 0.35 | 0.2 | 1.80 | 0.88 |
| 6 | Torrance | 5 | 0.84 | 0.33 | 0.2 | 1.67 | 0.84 |
| 7 | San Diego | 5.09 | 0.84 | 0.34 | 0.2 | 1.73 | 0.86 |
| 8 | Fullerton | 5.04 | 0.84 | 0.34 | 0.2 | 1.70 | 0.85 |
| 9 | Burbank | 5.21 | 0.84 | 0.35 | 0.2 | 1.82 | 0.88 |
| 10 | Riverside | 5.21 | 0.84 | 0.35 | 0.2 | 1.82 | 0.88 |
| 11 | Red Bluff | 4.87 | 0.84 | 0.33 | 0.2 | 1.59 | 0.82 |
| 12 | Sacramento | 4.91 | 0.84 | 0.33 | 0.2 | 1.61 | 0.83 |
| 13 | Fresno | 5.23 | 0.84 | 0.35 | 0.2 | 1.83 | 0.88 |
| 14 | Palmdale | 5.78 | 0.84 | 0.38 | 0.2 | 2.20 | 0.98 |
| 15 | Palm Springs | 5.74 | 0.84 | 0.38 | 0.2 | 2.17 | 0.97 |
| 16 | Blue Canyon | 4.98 | 0.84 | 0.33 | 0.2 | 1.66 | 0.84 |

TABLE 3
135 Degree (4:30) Configuration

| Climate | | | | | | Thermal | electrical |
|---|---|---|---|---|---|---|---|
| Zone | | GHI(KWHr/day/ | Optical | Thermal | Electrical | output(KWhr/day/ | output(KWhr/day/ |
| number | Area name | m2) | efficiency | efficiency | efficiency | m2) | m2) |
| 1 | Arcata | 3.93 | 0.84 | 0.22 | 0.2 | 0.87 | 0.66 |
| 2 | Santa Rosa | 4.64 | 0.84 | 0.29 | 0.2 | 1.35 | 0.78 |
| 3 | Oakland | 4.63 | 0.84 | 0.29 | 0.2 | 1.34 | 0.78 |
| 4 | San Jose | 4.96 | 0.84 | 0.31 | 0.2 | 1.56 | 0.84 |
| 5 | Santa Maria | 5.19 | 0.84 | 0.33 | 0.2 | 1.72 | 0.88 |
| 6 | Torrance | 5 | 0.84 | 0.32 | 0.2 | 1.59 | 0.84 |
| 7 | San Diego | 5.09 | 0.84 | 0.32 | 0.2 | 1.65 | 0.86 |
| 8 | Fullerton | 5.04 | 0.84 | 0.32 | 0.2 | 1.62 | 0.85 |
| 9 | Burbank | 5.21 | 0.84 | 0.33 | 0.2 | 1.73 | 0.88 |
| 10 | Riverside | 5.21 | 0.84 | 0.33 | 0.2 | 1.73 | 0.88 |
| 11 | Red Bluff | 4.87 | 0.84 | 0.31 | 0.2 | 1.50 | 0.82 |
| 12 | Sacramento | 4.91 | 0.84 | 0.31 | 0.2 | 1.53 | 0.83 |
| 13 | Fresno | 5.23 | 0.84 | 0.33 | 0.2 | 1.74 | 0.88 |
| 14 | Palmdale | 5.78 | 0.84 | 0.37 | 0.2 | 2.12 | 0.98 |
| 15 | Palm Springs | 5.74 | 0.84 | 0.36 | 0.2 | 2.09 | 0.97 |
| 16 | Blue Canyon | 4.98 | 0.84 | 0.32 | 0.2 | 1.57 | 0.84 |

TABLE 4
180 Degree (6 O’clock) Configuration

| Climate | | | | | | | electrical |
|---|---|---|---|---|---|---|---|
| Zone | | GHI | Optical | Thermal | Electrical | Thermal output | output |
| number | Area name | (KWHr/day/m2) | efficiency | efficiency | efficiency | (KWhr/day/m2) | (KWhr/day/m2) |
| 1 | Arcata | 3.93 | 0.84 | 0.22 | 0.2 | 0.86 | 0.66 |
| 2 | Santa Rosa | 4.64 | 0.84 | 0.29 | 0.2 | 1.34 | 0.78 |
| 3 | Oakland | 4.63 | 0.84 | 0.29 | 0.2 | 1.33 | 0.78 |
| 4 | San Jose | 4.96 | 0.84 | 0.31 | 0.2 | 1.55 | 0.84 |
| 5 | Santa Maria | 5.19 | 0.84 | 0.33 | 0.2 | 1.71 | 0.88 |
| 6 | Torrance | 5 | 0.84 | 0.32 | 0.2 | 1.58 | 0.84 |
| 7 | San Diego | 5.09 | 0.84 | 0.32 | 0.2 | 1.64 | 0.86 |
| 8 | Fullerton | 5.04 | 0.84 | 0.32 | 0.2 | 1.61 | 0.85 |
| 9 | Burbank | 5.21 | 0.84 | 0.33 | 0.2 | 1.72 | 0.88 |
| 10 | RiverSide | 5.21 | 0.84 | 0.33 | 0.2 | 1.72 | 0.88 |
| 11 | Red Bluff | 4.87 | 0.84 | 0.31 | 0.2 | 1.49 | 0.82 |
| 12 | Sacramento | 4.91 | 0.84 | 0.31 | 0.2 | 1.52 | 0.83 |
| 13 | Fresno | 5.23 | 0.84 | 0.33 | 0.2 | 1.73 | 0.88 |
| 14 | Palmdale | 5.78 | 0.84 | 0.36 | 0.2 | 2.11 | 0.98 |
| 15 | Palm Springs | 5.74 | 0.84 | 0.36 | 0.2 | 2.08 | 0.97 |
| 16 | Blue Canyon | 4.98 | 0.84 | 0.31 | 0.2 | 1.57 | 0.84 |

The performance of the solar cell is affected by the working temperature and cell type. The value of heat goes up with the working temperature of the collector, enabling a larger potential for applications using thermal energy. However, a higher working temperature reduces the solar cell efficiency and negatively impacts the amount and, therefore, the value of electricity generated. Thin film solar cells have lower degradation of efficiency under higher working temperature compared to crystalline cells such as mono-multi crystalline silicon cells. But silicon cells are more common in the market and relatively cheaper.

Embodiments that do not use a TCO topping will result in low thermal efficiency of the solar collector. However, such embodiments without a TCO topping also remove the risk of high stagnation temperatures. Using a solar cell with a TCO topping layer will limit the radiation loss, causing stagnation at a higher temperature, and potential damage to the solar cell if, for example, the heat transfer fluid in the device is not flowing for any reasons, such as during a power outage. Such stagnation may also happen during the installation stage, which may cause the tape or other adhesive used to join the solar cells with the minichannel to lose strength. However, such risks can be mitigated (e.g., by using a heat sink) and, in some embodiments, the added value of the high temperature heat generated (about 50% more heat) may justify using an alternate type of solar cell.

In some embodiments and to improve the thermal performance, argon gas is used to reduce about one third (⅓) of the free convection heat loss. The free convection simulation shows that the radiative heat loss will be dominant. Free convection heat loss is also be limited in embodiments in which the receiver is positioned at the horizontal (90°) configuration. Such a configuration also benefits the optical efficiency, especially if the reflectivity of the silver coating is not controlled well.

Methods of Making Combined Heat and Electricity Solar Collector

Methods of manufacturing combined heat and electricity solar collectors comprise (i) disposing a reflective coating on at least a portion of a surface of a housing (typically a glass tube); and (ii) positioning an absorber assembly inside the housing, the absorber assembly comprising one or more minichannels or heat pipes placed adjacent and/or attached to at least one solar cell, wherein the at least one solar sell converts solar light to electrical energy, and wherein the one or more minichannels or heat pipes provide cooling for the at least one solar cell by transferring heat to a fluid flowing through the one or more minichannels or heat pipes.

In some embodiments, the fluid flowing through the minichannels or heat pipes may be water. In other embodiments, the fluid flowing through the minichannels may be acetone, ethanol, methanol or ammonia.

In some embodiments the absorber assembly may be positioned in the housing radially at 90°, 135° or 180°. In other embodiments, the absorber assembly may be positioned radially in the housing anywhere from between 90° and 270°, wherein 0° is radially the highest point of the housing.

As described above, the housing may comprise any of glass, Plexiglas, polycarbonate, acrylic and/or other plastic materials. Most typically, the housing will comprise borosilicate and/or soda lime glass with a circular cross-section, but the cross-section may also be conical, parabolic or another geometric-shaped cross-section.

In some embodiments, the method further comprises sealing the housing and filling the housing with an inert gas. Most typically, the insert gas is argon and pressures within the housing are about one atmosphere (1 atm). In alternative embodiments, the method comprises evacuating the housing to create a vacuum, or a partial vacuum.

The method may also comprise adhering the at least one solar cell to the one or more minichannels with a high-temperature thermally conductive adhesive or with a double-sided, thermally-conductive heat tape.

In some embodiments, the absorber assembly comprises at least two minichannels, and the method further comprises connecting a bulkhead to an end of each of the at least two minichannels, the bulkhead configured to change a direction of the fluid flowing through at least one of the at least two minichannels to an opposite direction through the at least one other of the at least two minichannels. In other aspects, in lieu of a bulkhead, a U-bend may be utilized to redirect the fluid flow in the opposite direction from the initial direction of the flow in the minichannels.

In embodiments having two or more minichannels, the minichannels may be “stacked” on top of each other, or may be in a side-by-side arrangement. In embodiments where the minichannels are stacked, the flow may first be through a minichannel proximate to the interior surface of the housing and then through a minichannel more remote from the interior surface of the housing, or alternatively, the flow may be first through the minichannel remote from the interior of the housing, and then through the minichannel proximate to the interior surface of the housing.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

1. A solar collector, comprising:
a transparent tube;
a reflective coating disposed on at least a portion of the exterior surface of the transparent tube;
an absorber assembly positioned within the transparent tube, the absorber assembly comprising:
one or more minichannels, wherein a fluid flows through each of the minichannels;
at least one solar cell inside of the transparent tube and attached to the one or more minichannels, wherein the at least one solar cell converts solar light to electrical energy, and wherein heat generated by the at least one solar cell is transferred to the fluid.

2. The solar collector of claim 1, wherein the transparent tube has a circular cross-section.

3. The solar collector of claim 2, wherein the one or more minichannels are positioned on an inner circumference of the transparent tube between about 90 degrees and about 270 degrees, wherein 0 degrees is a highest point of the inner circumference of the transparent tube.

4. The solar collector of claim 1, wherein the transparent tube is glass.

5. The solar collector of claim 1, wherein the fluid is water.

6. The solar collector of claim 5, wherein the water ranges in temperature between about 10° C. and about 150° C.

7. The solar collector of claim 1, wherein the transparent tube is sealed and contains an inert gas.

8. The solar collector of claim 7, wherein the inert gas is argon.

9. The solar collector of claim 1, wherein the fluid is acetone.

10. The solar collector of claim 1, wherein the one or more minichannels comprise first and second minichannels adjacent to each other at respective surfaces in a stacked arrangement.

11. The solar collector of claim 1, wherein the one or more minichannels comprise aluminum.

12. The solar collector of claim 1, wherein a flowrate of the fluid is between 0.05 and 0.30 liters per minute.

13. The solar collector of claim 1, wherein the reflective coating comprises silver and is disposed on approximately a lower half of the transparent tube.

14. A solar collector, comprising:
a transparent cylindrical housing having (i) a circular cross-section, (ii) a closed first end and (iii) a second end;
a reflective coating disposed on a least a portion of the cylindrical housing;
an absorber assembly located inside of the housing, the absorber assembly comprising:
first and second minichannels adjacent to each other at respective surfaces;
at least one solar cell located in the cylindrical housing and attached to the first and second minichannels;
wherein the at least one solar cell converts solar light to electrical energy; and
wherein heat generated by the at least one solar cell is transferred to a fluid flowing through the first and second minichannels.

15. The solar collector of claim 14, wherein the fluid flows in a direction through the first minichannel, and flows in an opposite direction through the second minichannel.

16. The solar collector of claim 15, further comprising a bulkhead at and/or near the closed first end, and wherein the bulkhead redirects the fluid flow from the direction to the opposite direction.

17. A method of manufacturing a solar collector, the method comprising:
disposing a reflective coating on at least a portion of a glass tube;
positioning an absorber assembly inside of the glass tube, the absorber assembly formed by attaching at least one solar cell to one or more minichannels, wherein the at least one solar cell inside the tube converts solar light to electrical energy, and wherein the one or more minichannels provide cooling for the at least one solar cell by transferring heat to a fluid flowing through the one or more minichannels.

18. The method of claim 17, further comprising sealing the glass tube and filling the glass tube with an inert gas.

19. The solar collector of claim 17, further comprising adhering the two or more solar cells to the one or more minichannels using a high-temperature thermally conductive adhesive.

20. The solar collector of claim 17, wherein the one or more minichannels comprise two minichannels, and the method further comprises connecting a bulkhead to an end of each of the two minichannels, the bulkhead configured to change a direction of the fluid flowing through one of the two minichannels to an opposite direction through the other of the two minichannels.
